(19) United States
(12) Patent Application Publication
(10) Pub. No.: US 2006/0181195 A1
(43) Pub. Date: Aug. 17, 2006

(54) Light emitting display panel and method for inspecting the light emitting display panel

(75) Inventors: Yuta Oikawa, Yonezawa-shi (JP); Akihiko Yamaguchi, Yonezawa-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: TOHOKU PIONEER CORPORATION, Tendo-shi (JP)

(21) Appl. No.: 11/349,113

(22) Filed: Feb. 8, 2006

(30) Foreign Application Priority Data
Feb. 14, 2005 (JP) 2005-035988

(51) Int. Cl. H01J 1/62

(52) U.S. Cl. 313/498; 313/500

(57) ABSTRACT

In a light emitting display panel 1 including: a plurality of scanning lines B and a plurality of data lines A that intersect each other; and a plurality of light emitting devices E each of which is connected between each of the scanning lines B and each of the data lines A at an intersection of each of the scanning lines B and each of the data lines A, wherein the respective scanning lines B and the respective data lines A are driven by lighting driving means 2, 3, whereby the respective light emitting devices E are lighted, driven, and controlled, a display pixel area 21a is formed by the plurality of light emitting devices E to be lighted, driven, and controlled, and a plurality of pseudo light emitting devices Ed each having diode characteristics are arranged on at least two sides of the peripheral portion of the display pixel area 21a, and one electrode of each of the pseudo light emitting devices Ed is connected in common to one electrodes of the respective light emitting devices E via any one of the scanning lines B1 to Bm or the data lines A1 to An, and other electrodes of the respective pseudo light emitting devices Ed are connected in common to a scanning line B(m+1) or a data line A0 that is other than the scanning lines B1 to Bm or the data lines A1 to An, to which the light emitting devices E arranged in the display pixel area 21a are connected, and is connected in common to the pseudo light emitting devices Ed.

### BACKGROUND OF THE INVENTION

1. Field of the Invention

The present invention relates to a light emitting display panel of the type in which light emitting devices are arranged at the respective intersections of a plurality of scanning selection lines and a plurality of data lines, and a method for inspecting the light emitting display panel.

2. Description of the Related Art

Developments are being widely made in a display using a display panel constructed of light emitting devices arranged in a matrix. An organic EL (electroluminescence) device using an organic material for a light emitting layer has received attention as a light emitting device used for such a display panel. As a backdrop to this, it is also thought that by using an organic material expected to have excellent light emitting characteristics for the light emitting layer of an EL device, the EL device has come to have such a high efficiency and such a long life that are sufficient for practical applications.

As a display panel using such an organic EL device are proposed a passive matrix type display panel (refer to, for example, Japanese Unexamined Patent Publication No. 2003-288053) in which EL devices are simply arranged in a matrix and an active matrix type display panel (refer to, for example, Japanese Unexamined Patent Publication No. 2003-316315) in which active devices each made of a TFT are added to the respective EL devices arranged in a matrix.

In FIG. 1 is shown a passive matrix driving system and one example of a display panel having light emitted and controlled by the system. A method for driving an organic EL device in this passive matrix driving system includes two methods of a cathode line scanning/anode line driving method and an anode line scanning/cathode line driving method. Then, the construction shown in FIG. 1 shows the embodiment of the former cathode line scanning/anode line driving method.

That is, on a display panel 1, anode lines A1 to An as n driving lines are arranged in a longitudinal direction and cathode lines B1 to Bm as m scanning lines are arranged in a lateral direction and organic EL devices E each shown by a symbol mark of diode are arranged at the respective intersections (a total of n×m points) of the anode lines and the cathode lines. In this manner, the display panel 1 is constructed. Then, the respective EL devices E as the light emitting devices constructing respective pixels are arranged in the shape of a lattice and in correspondence with the intersections of the anode lines A1 to An along a vertical direction and the cathode lines B1 to Bm along a horizontal direction, one ends of the respective EL devices (anode terminals of the EL devices) are connected to the respective anode lines and other ends (cathode terminals of the EL devices) are connected to the respective cathode lines. Then, the anode lines are connected to and driven by an anode line driving circuit 2 and the cathode lines are connected to and driven by a cathode line scanning circuit 3, respectively.

The above-mentioned cathode line scanning circuit 3 is provided with scanning switches Sy1 to Sym in correspondence with the respective cathode scanning lines B1 to Bm, and the scanning switches Sy1 to Sym act in such a way as to connect either a reverse bias voltage VM from a reverse bias voltage producing circuit 5 for preventing the cross-talk light emitting of the devices or the earth potential as a reference potential point to corresponding cathode scanning lines. Then, the anode line driving circuit 2 is provided with constant-current circuits I1 to In for supplying driving currents to the individual EL devices through the respective anode lines and driving switches Sx1 to Sxn.

The above-mentioned driving switches Sx1 to Sxn act in such a way as to connect either currents from the constant-current circuits I1 to In or the earth potential to the corresponding anode lines. Hence, when the driving switches Sx1 to Sxn are connected to the above-mentioned constant-current circuit sides, the driving switches Sx1 to Sxn act in such a way as to supply currents from the constant-current circuits I1 to In to the individual EL devices arranged in correspondence with the cathode scanning lines.

In this regard, a voltage power source such as a constant-voltage circuit in place of the above-mentioned constant-current circuit can be used. However, while the current/brightness characteristic of the EL device is stable to a temperature change, the voltage/brightness characteristic of the EL device is unstable to a temperature change. Moreover, there is a possibility that the EL device might be degraded by an overcurrent. For these reasons, the constant-current circuit as shown in FIG. 1 is usually employed.

The above-mentioned anode line driving circuit 2 and cathode line scanning circuit 3 have a control bus connected thereto from a light emission controlling circuit 4 including a CPU, and the above-mentioned scanning switches Sy1 to Sym and driving switches Sx1 to Sxn are operated on the basis of the signal of an image to be displayed. With this, the constant-current circuits I1 to In are connected as appropriate to the desired anode lines while the cathode scanning lines are set at the earth potential at a specified period on the basis of the image signal. Therefore, the above-mentioned individual EL light emitting devices selectively emit light to display an image based on the above-mentioned image signal on the display panel 1.

The respective constant-current circuits I1 to In in the above-mentioned anode line driving circuit 2 have a DC output (output voltage=VH) supplied from, for example, a driving voltage power source 6 of a boosting type DC-DC converter. With this, constant currents produced by the above-mentioned constant-current circuits I1 to In having the output voltage VH supplied from the driving voltage power source 6 are supplied to the individual EL devices arranged in correspondence with the anode scanning lines.

Meanwhile, the value of the reverse bias voltage VM used for preventing the cross-talk light emission of the EL device is comparatively close to the value of the output voltage VH, and the current consumption of the reverse bias voltage VM is smaller as compared with the current consumption of the output voltage VH. For these reasons, generally, the output voltage VH is regulated in series to produce the reverse bias voltage VM. In FIG. 1, it is the reverse bias voltage producing circuit that functions as this series regulator. The adoption of this construction is thought to be more advantageous in terms of the number of parts and current consumption.

By the way, in recent years, in the light emitting display panel using the EL devices, a display function of higher definition has been required and with this, there is a tendency to make the area of each pixel finer. However, when one pixel is made finer (the pixel is reduced in area), its electrostatic capacitance is also made smaller. For this reason, in the display panel having fine pixels, there is apprehension that the electric charges charged by a surge of static electricity or the like flow into the pixels in the manufacturing process and the like to cause damage to the organic film.

The damage caused by this surge will be described by the use of FIG. 2 and FIG. 3. FIG. 2 is a diagram schematically showing the arrangement relationship between a pixel area 20 and anode leader terminals and cathode leader terminals formed on the display panel 1 shown in FIG. 1. FIG. 3 is an enlarged view of a portion in FIG. 2. Here, the leader terminals mean terminals provided outside the pixel area 20 so as to electrically connect anode lines and cathode lines formed in the pixel area 20 to the anode line driving circuit 2 and the cathode line scanning circuit 3, respectively.

For example, as shown in FIG. 1, in the case of a panel structure in which the scanning lines (cathode lines) are led from the left side of the pixel area 20 and in which the driving lines (anode lines) are led from the upper side of the pixel area 20, there is an arrangement relationship shown in FIG. 2 between the pixel area 20 and the anode leader terminals 7 and the cathode leader terminals 8. Then, as shown in the enlarged view in FIG. 3, there is an arrangement relationship shown in FIG. 3 between pixels (E) in the pixel area 20 and the leader terminals 7,8. Here, when the anode leader terminals 7 and the cathode leader terminals 8 are electrically charged by the surge of static electricity or the like, the electric charges flow into the pixels electrically connected to the terminals 7, 8 via the anode lines and cathode lines. When the pixels are fine, the pixels are small in electrostatic capacitance and hence even if the voltage is very small (for example, several tens V), the pixels suffer damage (dielectric breakdown or the like). In this regard, which pixels suffer damage (dielectric breakdown or the like) is determined by the factors of the thickness of the layer, dielectric resistance, or the like, and hence to specify the pixels to suffer damage is difficult.

Moreover, when the damage (dielectric breakdown or the like) to the pixel is large, there is presented a problem that the dielectric resistance of the pixel is reduced to produce a leak current to make the pixel faulty. In this case, for example, when a leak current develops in a pixel E1 shown FIG. 1 and the pixel E1 becomes faulty, if a reverse bias voltage is applied to the pixel E1, current flows in a direction shown by a broken line with arrow in the drawing. That is, current flows through the device on a scanning line by the application of the reverse bias voltage to produce voltage by scanning line resistance to develop the phenomenon of changing a scanning potential. As for this phenomenon, when light emitting duty is long, there is no problem because constant current is predominant but when light emitting duty is short, there is presented a problem that the brightness of a light emitting area is reduced.

In this regard, conventional technologies for reducing the occurrence of the above-mentioned leak current include a method of irradiating a pixel suffering damage (dielectric breakdown or the like) with laser to break the pixel. However, in the case of using this method, there is presented a problem that as a pixel area is small, the rate of a light emitting area after the laser irradiation is reduced by a large amount. Therefore, when the pixel area is small, it is a problem how to reduce the damage (dielectric breakdown or the like) to the display pixel.

### SUMAMRY OF THE INVENTION

This invention has been made in view of the above-mentioned technical problems. The object of the present invention is to provide a light emitting display panel having light emitting devices arranged at intersections of a plurality of scanning lines and a plurality of data lines that intersect each other and capable of preventing the inflow of electric charges into the light emitting devices to be lighted and driven from being caused by a surge to reduce damage to display pixels, and a method for inspecting the light emitting display panel.

A light emitting display panel according to the present invention made to solve the above-mentioned problems is a light emitting display panel of the type including: a plurality of scanning lines and a plurality of data lines that intersect each other; and a plurality of light emitting devices each of which is connected between each of the scanning lines and each of the data lines at an intersection of each of the scanning lines and each of the data lines, wherein the respective scanning lines and the respective data lines are driven by lighting driving means, whereby the respective light emitting devices are lighted, driven, and controlled, and

characterized in that a display pixel area is formed by the plurality of light emitting devices to be lighted, driven, and controlled, and a plurality of pseudo light emitting devices each having diode characteristics are arranged on at least two sides of a peripheral portion of the display pixel area; one electrode of each of the pseudo light emitting devices being connected in common to one electrodes of the respective light emitting devices via any one of the scanning lines or the data lines; other electrodes of the respective pseudo light emitting devices being connected in common to a scanning line or a data line that is other than the scanning lines or the data lines, to which the light emitting devices arranged in the display pixel area are connected, and is connected in common to the pseudo light emitting devices.

Moreover, a method for inspecting a light emitting display panel according to the present invention made to solve the above-mentioned problems is an inspection method in a manufacturing process of a light emitting display panel of the type including: a plurality of scanning lines and a plurality of data lines that intersect each other; and a plurality of light emitting devices each of which is connected to each of the scanning lines and each of the data lines at an intersection of each of the scanning lines and each of the data lines, wherein the respective scanning lines and the respective data lines are driven by lighting driving means, whereby the respective light emitting devices are lighted, driven, and controlled, and

characterized in that a display pixel area is formed by the plurality of light emitting devices to be lighted, driven, and controlled, and a plurality of pseudo light emitting devices each having diode characteristics are arranged on at least two sides of a peripheral portion of the display pixel area; one electrode of each of the pseudo light emitting devices being connected in common to one electrodes of the respective light emitting devices via any one of the scanning lines or the data lines; other electrodes of the respective pseudo light emitting devices being connected in common to a scanning line or a data line that is other than the scanning lines or the data lines, to which the light emitting devices arranged in the display pixel area are connected, and is connected in common to the pseudo light emitting devices, and

is characterized by implementing the step of connecting the scanning line and the data line, to which the plurality of pseudo light emitting devices are connected in common and which are not connected to the lighting driving means, to the lighting driving means; and the step of lighting and driving the respective pseudo light emitting devices by the lighting driving means.

### BRIEF DESCRIPTION OF THE DRAWINGS

FIG. 1 is a block diagram showing one example of a conventional display panel having light emission controlled by a passive matrix driving system and a driving circuit of the display panel;

FIG. 2 is a diagram schematically showing the arrangement relationship between a pixel area and anode leader terminals and cathode leader terminals in the display panel shown in FIG. 1;

FIG. 3 is an enlarged view of a portion in FIG. 2;

FIG. 4 is a block diagram showing one embodiment of a light emitting panel according to the present invention and a driving circuit of the light emitting panel;

FIG. 5 is a diagram schematically showing the arrangement relationship between a pixel area and anode leader terminals and cathode leader terminals in the display panel shown in FIG. 4;

FIGS. 6A and 6B are enlarged views of a portion in FIG. 5;

FIG. 7 is a diagram schematically showing another embodiment of the arrangement relationship between a pixel area and anode leader terminals and cathode leader terminals in the display panel shown in FIG. 4;

FIG. 8 is a diagram schematically showing still another embodiment of the arrangement relationship between a pixel area and anode leader terminals and cathode leader terminals in the display panel shown in FIG. 4;

FIG. 9 is a diagram schematically showing still another embodiment of the arrangement relationship between a pixel area and anode leader terminals and cathode leader terminals in the display panel shown in FIG. 4;

FIG. 10 is a diagram schematically showing still another embodiment of the arrangement relationship between a pixel area and anode leader terminals and cathode leader terminals in the display panel shown in FIG. 4; and

FIG. 11 is a block diagram shown one embodiment of a lighting driving circuit showing a method for inspecting a light emitting display panel according to the present invention.

### DETAILED DESCRIPTION OF THE PREFERRED EMBODIMENTS

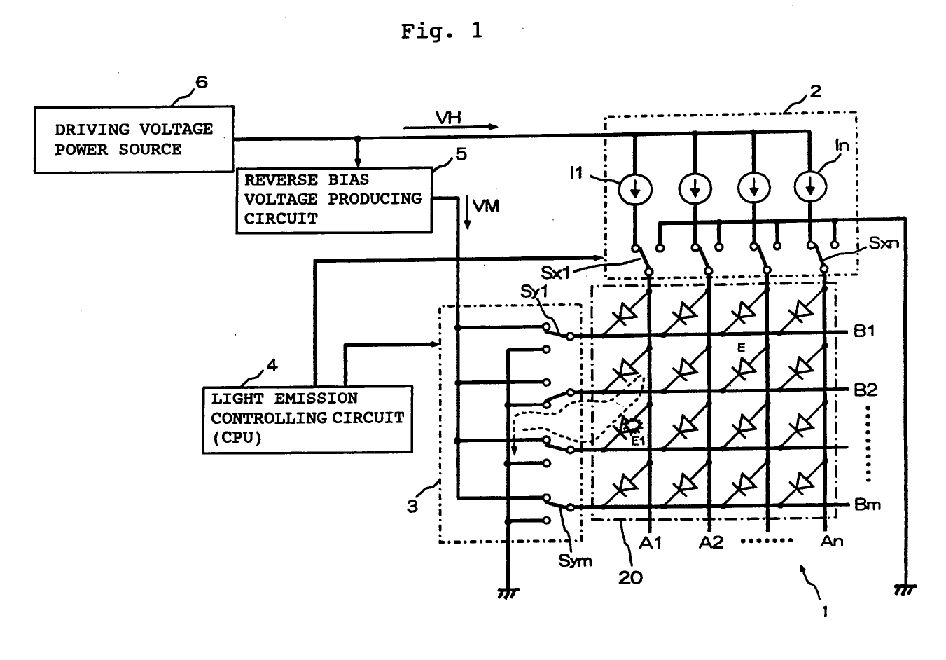

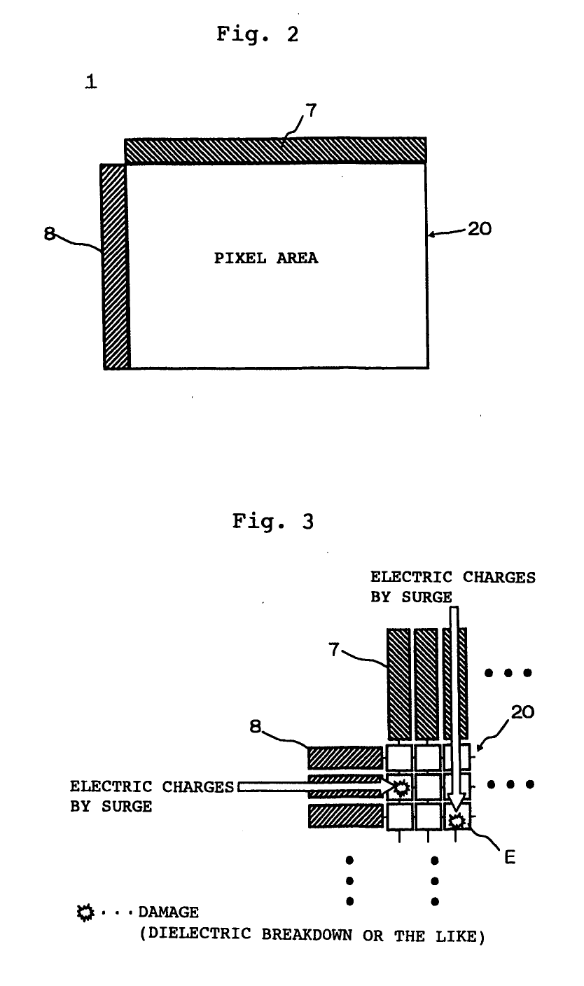

Hereinafter, a light emitting display panel according to this invention and an inspection method in a process for manufacturing the light emitting display panel will be described on the basis of embodiments shown in the drawings. In the following description, parts corresponding to the respective parts having been already described and shown in FIG. 1 to FIG. 3 are denoted by the same reference characters and hence their individual functions and operations will be omitted as appropriate.

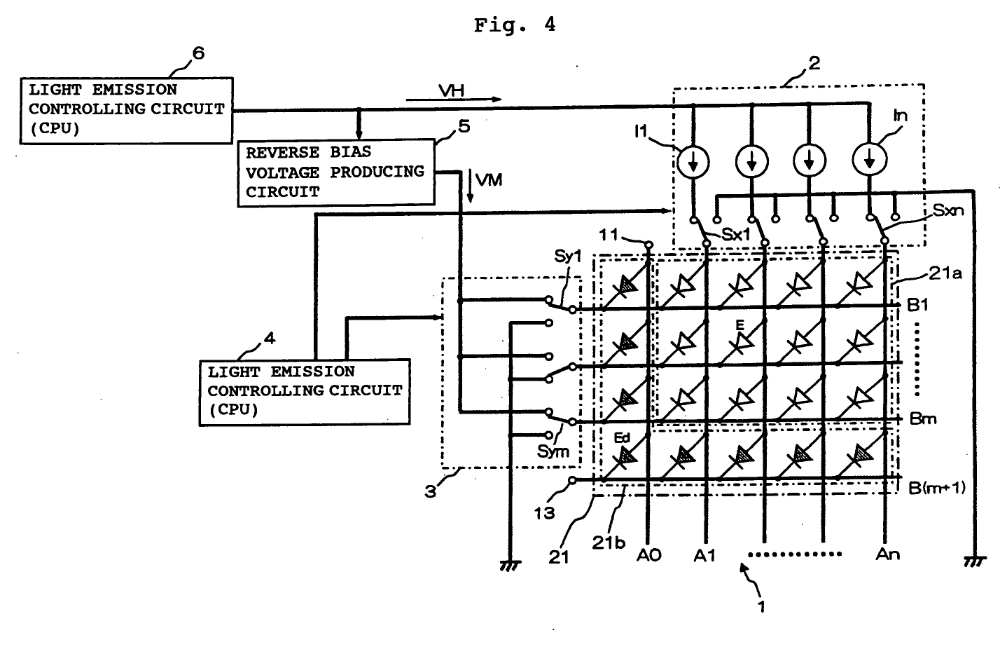

FIG. 4 is a diagram showing one embodiment of a cathode line scanning/anode line driving circuit having a light emitting display panel according to this invention. Describing the difference between FIG. 4 and FIG. 1 showing a conventional embodiment, in FIG. 4, first, an anode line A0 is added to the left side of anode lines A1 to An and a cathode line B(m+1) is added to the lower side of cathode lines B1 to Bm. Then, EL devices Ed as pseudo light emitting devices are arranged at the respective intersections of the anode line A0 and the cathode lines B1 to Bm, respectively. Then, EL devices Ed as pseudo light emitting devices are arranged also at the respective intersections of the cathode line B(m+1) and the anode lines A1 to An, respectively.

That is, one electrode of each of the EL devices Ed as the pseudo light emitting devices is connected in common to one electrodes of the other EL devices E, which are other than the pseudo light emitting devices, via any one of the cathode lines B1 to Bm or the anode lines A1 to An. Then, the other electrodes of the respective EL devices Ed are connected in common to the cathode line B(m+1) or the anode line A0. Here, in FIG. 4 is shown an embodiment in which an EL device Ed is arranged also at the intersection of the cathode line B(m+1) and the anode line A0.

Moreover, a leader terminal 11 is formed at one end of the anode line A0 and is brought to a state (open state) where this leader terminal 11 is not connected to an anode line driving circuit 2 of lighting driving means, that is, constant-current circuits I1 to In and driving switches SX1 to SXn. Then, a leader terminal 13 is formed at one end of the cathode line B(m+1) and is brought to a state (open state) where this leader terminal 13 is not connected to a cathode line scanning circuit 3 of lighting driving means, that is, scanning switches SY1 to SYm.

In this manner, the above-mentioned plurality of EL devices Ed, the pseudo light emitting devices, are provided as dummy devices (referred to as “dummy devices Ed”) that are not usually lighted and driven. In the following description, an area where the EL devices E are lighted and driven by the anode line driving circuit 2 and the cathode line scanning circuit 3 in a pixel area 21 on a display panel 1 shown in FIG. 4 is referred to as a display pixel area 21a. Meanwhile, an area where the dummy devices Ed, the pseudo light emitting devices, are arranged in the pixel area 21 is referred to as a dummy pixel area 21b. That is, the pixel area 21 is divided into the display pixel area 21a and the dummy pixel area 21b.

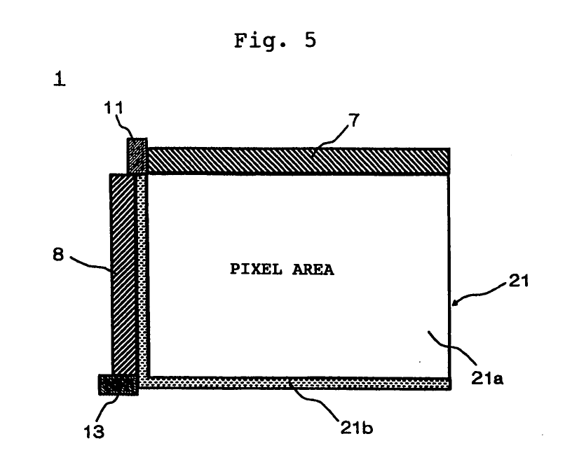

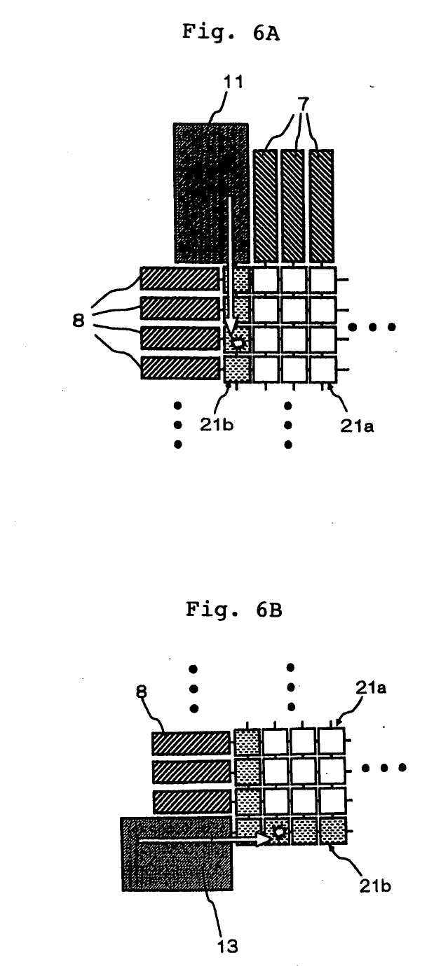

FIG. 5 is a schematic diagram showing the arrangement relationship between the pixel area and the anode leader terminal and cathode leader terminal in the light emitting panel according to the present invention shown in FIG. 4. FIGS. 6A and 6B are enlarged views of a portion in FIG. 5. As shown in the drawings, the anode leader terminals 7 led from the anode lines A1 to An are arranged on the upper side of and next to the pixel area 21 and the plurality of cathode leader terminals 8 led from the cathode lines B1 to Bm are arranged on the left side of and next to the display panel 1.

Meanwhile, a leader terminal 11 led from the anode line A0 not connected to the anode line driving circuit 2 is arranged on the left end portion of and next to the anode leader terminal 7 of the display panel 1 as shown in FIG. 5 and FIG. 6A. Then, a leader terminal 13 led from the cathode line B(m+1) not connected to the cathode line scanning circuit 3 is arranged on the lower end portion of and next to the cathode leader terminal 8 as shown in FIG. 5 and FIG. 6B. Then, as shown in the enlarged views in FIG. 6, the leader terminals 11, 13 are made larger in width and length than the respective anode leader terminals 7 and the respective cathode leader terminals 8, thereby being so formed as to have a larger surface area.

In this manner, the leader terminals 11, 13 led from the dummy pixel area 21b are so formed as to have a larger surface area. Therefore, for example, even if a surge of static electricity or the like is emitted to the display panel 1 in the manufacturing process of the display panel 1, emitted electric charges are introduced to the connection terminals 11, 13 having larger capacity than the respective anode connection terminals 7 and the respective cathode connection terminals 8. As a result, the electric charges by the surge flow into the dummy pixel area 21b and hence any one of the dummy devices Ed suffers damage. Therefore, the display pixel area 21a on the display panel 1 that is actually lighted and driven to emit light does not suffer damage and hence the dielectric breakdown of the display pixels can be prevented. Because the leader terminals 11, 13 are opened (electrically cut), when a dielectrically broken dummy device Ed exists, the phenomenon of producing a leak current via the dummy device can be avoided.

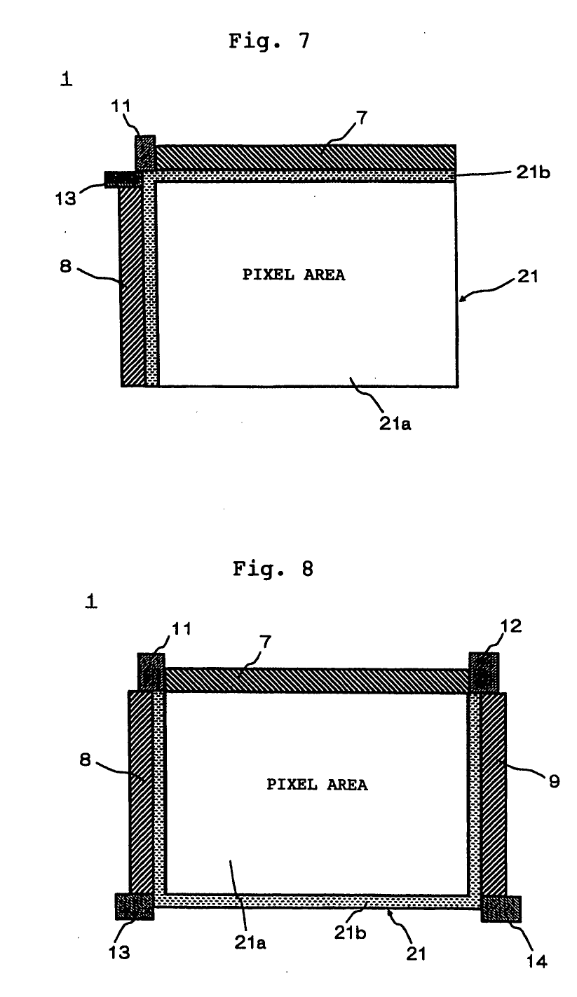

In the embodiment shown in FIG. 4 and FIG. 5, an example of which dummy pixel areas 21b is formed on two sides of the lower and left sides of the display pixel area 21a is shown. However, this is not alone but the dummy pixel area 21b may be formed on two sides of the upper and left sides of the display pixel area 21a as shown in FIG. 7. However, in this case, as shown in the drawing, the leader terminal 13 is arranged on the upper end of and next to the cathode leader terminal 8.

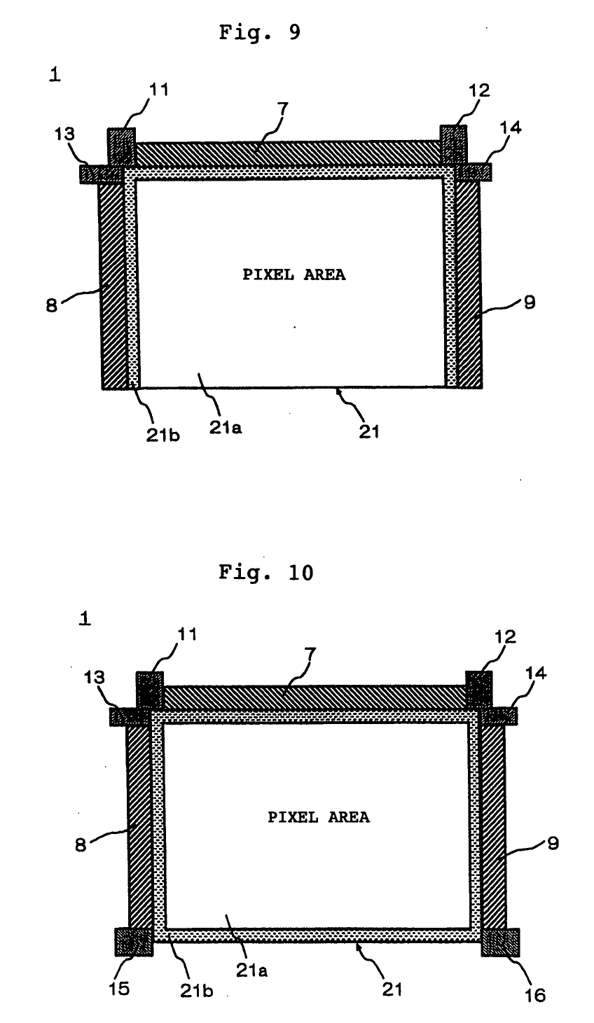

Moreover, in the case of a structure in which scanning lines (cathode lines) are led from both of the left and right sides of the display panel 1, as shown in FIG. 8 and FIG. 9, the cathode leader terminals 8, 9 are arranged on the left and right sides of the display pixel area 21a and hence it is essential only that the dummy pixels Ed are arranged on two sides of the left and right sides of the display pixel area 21a and on any one side of the upper and lower sides. In this case, there is provided a construction in which leader terminals 11, 12 led from anode lines not connected to the anode line driving circuit 2 are arranged and in which leader terminals 13, 14 led from the cathode lines not connected to the cathode line scanning circuit 3 are arranged. According to this construction, electric charges emitted from a surge of static electricity or the like are introduced to the leader terminals 11, 12, 13, 14 each having a larger surface area (larger capacity) than the anode leader terminal 7 and the cathode leader terminal 8 each of which has a smaller surface area. As a result, the electric charges flow to the dummy pixel area 21b to cause damage to the dummy devices Ed whereas the other EL devices for display can be avoided from electrostatic breakdown.

Furthermore, in the case of a structure in which the scanning lines (cathode lines) are led from both of the left and right sides of the display panel 1, as shown in FIG. 10, it is also recommended that the dummy devices Ed are arranged on two sides of the left and right sides of the display pixel area 21a and that the dummy devices Ed are arranged also on two sides of the upper and lower sides. In this case, as shown in the drawing, there is provided a structure in which the leader terminals 11, 12 led from the anode lines not connected to the anode line driving circuit 2 are arranged and in which leader terminals 13, 14, 15, 16 led from the cathode lines not connected to the cathode line scanning circuit 3 are arranged. According to this construction, the entire periphery of the display pixel area 21a is surrounded by the dummy pixel area 21b and the electric charges emitted by the surge can be introduced to the dummy devices Ed with reliability.

As described above, according to one embodiment of the light emitting display panel in accordance with the present invention, the dummy light emitting devices are arranged on the anode line and the cathode line not connected to the lighting driving means and the surface areas of the leader terminals led from these anode line and cathode line are made larger than the surface areas of the leader terminals led from the anode lines and the cathode lines connected to the light emitting devices to be lighted and driven, whereby the flow of electric charges by a surge of static electricity or the like can be introduced to the dummy light emitting devices. As a result, even if the respective pixels are fine, damage by the surge is done to the dummy light emitting devices and a bad effect made on the light emitting devices actually lighted and driven can be avoided.

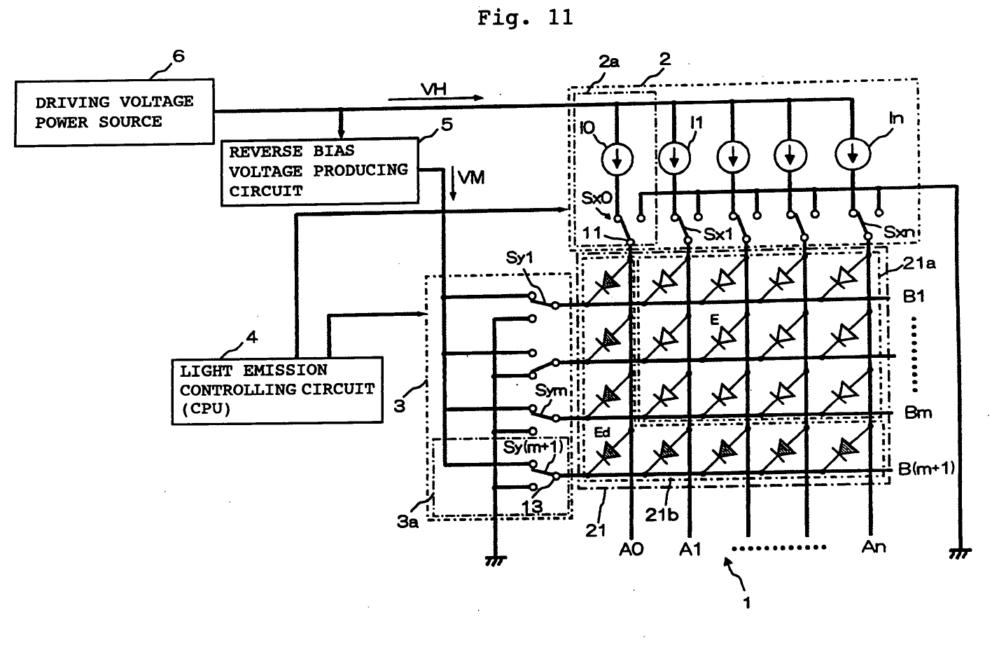

Successively, one embodiment of an inspection method in the manufacturing process of a light emitting display panel according to the present invention will be described on the basis of FIG. 11. FIG. 11 is a circuit diagram for inspection in embodiment at the time of inspecting the display panel 1 shown in FIG. 4. A circuit shown in FIG. 11 is constructed in such a way that an anode line driving circuit 2a for inspection and a cathode line scanning circuit 3a for inspection are added as circuits for inspection to the circuit in FIG. 4.

As shown in the drawing, the anode line driving circuit 2a for inspection is constructed of a constant-current circuit I0 and a driving switch SX0. Then, the constant-current circuit I0, like the other constant-current circuits I1 to In, is supplied with a DC output from the driving voltage power source 6 and the driving switch Sx0 connects the constant-current circuit I0 to the leader terminal 11 of the anode line A0. Then, the cathode line scanning circuit 3a for inspection has a scanning switch Sy(m+1) and this switch is connected to the leader terminal 13 of the cathode line B(m+1).

The inspection process in the manufacturing process of the display panel 1 will be performed in the following procedure. First, the leader terminal 11 of the anode line A0 not connected to the anode line driving circuit 2 as the lighting driving means is connected to the anode line driving circuit 2a for inspection as lighting driving means and the leader terminal 13 of the cathode line B(m+1) not connected to the cathode line scanning circuit 3 as the lighting driving means is connected to the cathode line scanning circuit 3a for inspection as lighting driving means. Then, the anode line driving circuit 2a for inspection and the cathode line scanning circuit 3a for inspection are driven to light and drive the dummy devices Ed in the dummy pixel area 21b.

According to the above-mentioned process, when a device of the light emitting devices including the dummy devices Ed suffers damage by the surge of static electricity or the like and hence is dielectrically broken, a leak current develops in the pixel of the device and hence the device can be recognized as a bright point or a dark point. In this manner, it is possible to inspect the presence or absence of a dummy device suffering damage (dielectric breakdown or the like) in the dummy pixel area 21b and the presence or absence of an EL device suffering damage in the display pixel area 21a, and hence to know the occurrence of surge and the tendency of the effect. When the inspection is finished, the anode line driving circuit 2a for inspection and the cathode line scanning circuit 3a for inspection are cut from the leader terminals 11, 13. Then, when an EL device suffering damage exists in the display pixel area 21a, the EL device is repaired as required.

As described above, according to one embodiment of the inspection method of a display panel according to the present invention, the leader terminal 11 of the anode line A0 not connected to the lighting driving means is connected to the lighting driving means, and the leader terminal 13 of the cathode line B(m+1) not connected to the lighting driving means is connected to the lighting driving means, and the lighting driving means is driven. With this, it is possible to inspect the presence or absence of a device broken by a surge in the dummy pixel area 21 band the display pixel area 21a. Then, with this, the effect of the surge on the display panel 1 can be recognized and hence the inspection result can be fed back to the surge measures in the manufacturing process.

In this regard, in the above-described embodiment has been shown the case of a cathode line scanning/anode line driving method in a passive matrix driving system. However, even in the case of an anode line scanning/cathode line driving method or in the case of an active matrix driving system, the display panel according to the present invention and the inspection method of the display panel can be suitably applied.

What is claimed is:

1. A light emitting display panel comprising: a plurality of scanning lines and a plurality of data lines that intersect each other; and a plurality of light emitting devices each of which is connected between each of the scanning lines and each of the data lines at an intersection of each of the scanning lines and each of the data lines, wherein the respective scanning lines and the respective data lines are driven by lighting driving means, whereby the respective light emitting devices are lighted, driven, and controlled,
wherein a display pixel area is formed by the plurality of light emitting devices to be lighted, driven, and controlled, and a plurality of pseudo light emitting devices each having diode characteristics are arranged on at least two sides of a peripheral portion of the display pixel area; one electrode of each of the pseudo light emitting devices being connected in common to one electrodes of the respective light emitting devices via any one of the scanning lines or the data lines; other electrodes of the respective pseudo light emitting devices being connected in common to a scanning line or a data line that is other than the scanning lines or the data lines, to which the light emitting devices arranged in the display pixel area are connected, and is connected in common to the pseudo light emitting devices.

2. The light emitting display panel according to claim 1, wherein leader terminals are formed at end portions of the respective scanning lines and the respective data lines, each of the leader terminals of the scanning line and the data line to which the pseudo light emitting devices are connected in common has a larger surface area than each of the leader terminals of the scanning lines and the data lines to which the light emitting devices in the display area are connected.

3. The light emitting display panel according to claim 1, wherein the leader terminals of the scanning line and the data line to which the pseudo light emitting devices are connected in common are not connected to the lighting driving means.

4. The light emitting display panel according to claim 2, wherein the leader terminals of the scanning line and the data line to which the pseudo light emitting devices are connected in common are not connected to the lighting driving means.

5. The light emitting display panel according to any one of claims 1 to 4, wherein the light emitting devices in the display pixel area and the pseudo light emitting devices are constructed of organic EL devices.

6. A method for inspecting a light emitting display panel in a manufacturing process of the light emitting display panel comprising:
a plurality of scanning lines and a plurality of data lines that intersect each other; and a plurality of light emitting devices each of which is connected to each of the scanning lines and each of the data lines at an intersection of each of the scanning lines and each of the data lines, wherein the respective scanning lines and the respective data lines are driven by lighting driving means, whereby the respective light emitting devices are lighted, driven, and controlled, and
characterized in that a display pixel area is formed by the plurality of light emitting devices to be lighted, driven, and controlled, and a plurality of pseudo light emitting devices each having diode characteristics are arranged on at least two sides of a peripheral portion of the display pixel area; one electrode of each of the pseudo light emitting devices being connected in common to one electrodes of the respective light emitting devices arranged in the display pixel area via any one of the scanning lines or the data lines; other electrodes of the respective pseudo light emitting devices being connected in common to a scanning line or a data line that is other than the scanning lines or the data lines, to which the light emitting devices arranged in the display pixel area are connected, and is connected in common to the pseudo light emitting devices,
wherein the method comprising the steps of:
connecting the scanning line and the data line, to which the plurality of pseudo Light emitting devices are connected in common and which are not connected to the lighting driving means, to the lighting driving means; and
lighting and driving the respective pseudo light emitting devices by the lighting driving means.
